(19) United States
(12) Patent Application Publication
(10) Pub. No.: US 2026/0165038 A1
(43) Pub. Date: Jun. 11, 2026

(54) ReRAM WITH INERT CAP LAYER

(71) Applicants: INTERNATIONAL BUSINESS MACHINES CORPORATION, Armonk, NY (US); TOKYO ELECTRON LIMITED, Tokyo (JP)

(72) Inventors: Kevin Wayne Brew, Niskayuna, NY (US); Takashi Ando, Eastchester, NY (US); Paul Charles Jamison, Averill Park, NY (US); Steven P. Consiglio, Voorheesville, NY (US); Kenichi Imakita, Albany, NY (US); Takaaki Tsunomura, Tokyo (JP)

(21) Appl. No.: 18/972,239

(22) Filed: Dec. 6, 2024

(51) Int. Cl. H10N 70/20; H10B 63/00; H10N 70/00

(52) U.S. Cl. CPC H10N 70/24; H10B 63/80; H10N 70/023; H10N 70/063; H10N 70/8265; H10N 70/841; H10N 70/8833

(57) ABSTRACT

A memristor device includes a bottom electrode, an active resistive random-access memory (ReRAM) layer disposed on the bottom electrode and an oxygen reservoir layer disposed on the active ReRAM layer. An inert cap layer is disposed on the oxygen reservoir layer. A top electrode is disposed on the inert cap layer.

### BACKGROUND

The present invention generally relates to semiconductor devices and processing methods, and more particularly to memristor devices for artificial neural networks.

Machine learning often relies on artificial neural networks (ANNs), which are computational models inspired by biological neural networks in human or animal brains. An ANN includes a set of connected units or nodes, called artificial neurons. Signals are transmitted along connections (also called edges) between artificial neurons, similarly to synapses. That is, an artificial neuron that receives a signal processes it and then signals connected neurons. Connection weights (also called synaptic weights) are associated with the connections and nodes. Each neuron may have several inputs and a connection weight is attributed to each input (the weight of that specific connection). Such weights adjust as learning proceeds.

In neuromorphic computing applications, a resistive memory device can be used as a connection (synapse) between a pre-neuron and post-neuron, representing the connection weight in the form of device resistance. Multiple pre-neurons and post-neurons can be connected through a crossbar array of resistive random-access memory (ReRAM), which expresses a fully-connected neural network.

A neural network implemented in hardware can include the crossbar array structure for performing the synaptic interconnect operations, processing electrical or optical signals. Crossbar arrays of memristors can include, e.g., a phase-change memory (PCM) device, ReRAM, a magnetic random-access memory (SRAM), etc. A memristor is a non-linear, two-terminal electrical component, which regulates the flow of electrical current and remembers its conductive state. Furthermore, the resistance of a memristor depends on the history of electric signals applied though the device. A memristor is non-volatile (NV) as it retains memory without power and does not change its state for small electrical signals when a reading operation is performed.

### SUMMARY

In accordance with an embodiment of the present invention, a memristor device includes a bottom electrode, an active resistive random-access memory (ReRAM) layer disposed on the bottom electrode and an oxygen reservoir layer disposed on the active ReRAM layer. An inert cap layer is disposed on the oxygen reservoir layer. A top electrode is disposed on the inert cap layer.

In accordance with another embodiment of the present invention, a memristor device includes a bottom electrode, an active resistive random-access memory (ReRAM) layer disposed on the bottom electrode and an oxygen reservoir layer disposed on the active ReRAM layer and including a metal oxide. An inert cap layer is disposed on the oxygen reservoir layer, wherein the inert cap layer includes a material having a work function above 4.5 eV. A top electrode is disposed on the inert cap layer.

In accordance with another embodiment of the present invention, a method of fabricating a memristor device includes forming a bottom electrode, depositing an active resistive random-access memory (ReRAM) layer on the bottom electrode, depositing an oxygen reservoir layer on the active ReRAM layer, depositing an inert cap layer on the oxygen reservoir layer and forming a top electrode on the inert cap layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 is a perspective view showing a crossbar array having ReRAM structures in accordance with present embodiments;

FIG. 2 is a cross-sectional view showing a ReRAM stack after a blanket deposition in accordance with present embodiments;

FIG. 3 is a cross-sectional view showing the ReRAM stack after a subtractive etch process to define a memristor in accordance with present embodiments; and

FIG. 4 is a cross-sectional view showing the ReRAM stack after a protection/passivation layer or spacers are formed to protect sidewalls from oxidation in accordance with present embodiments.

### DETAILED DESCRIPTION

In accordance with embodiments of the present invention, devices and methods are described which include memristor devices for resistive random-access memory (ReRAM). The memristors can include two electrodes (e.g., a top and a bottom electrode) having an oxygen reservoir layer, such as e.g., a metal oxide (MO) material, disposed therebetween. In an embodiment, the MO is in-situ capped (or includes a low queue-time deposition) where a thin conductive cap layer is formed to reduce oxygen gettering. The thin conductive cap layer can include a thickness of between about 0.5 nm to about 5 nm. The thin conductive cap layer includes a high work function with respect to the bottom electrode, to which it connects, to ensure a lower operating voltage. The high work function material of the thin conductive cap layer can include a value greater than about 4.5 eV. Since the memristors are assembled from the bottom electrode to the top electrode, preservation of the MO layer prevents reaction with air and gettering during deposition of the top electrode metals. By using an in-situ thin conductive cap layer, the MO is protected and enables integration with typical integrated circuit material sets. In-situ processing refers to methods carried out in sequence without exposing the wafer being processed to air between the process steps.

In accordance with embodiments of the present invention, an electrical memristor device includes a layer ReRAM stack structure comprising: two electrodes including a bottom electrode and a top electrode. An active ReRAM layer is formed on the bottom electrode from an electrically conductive filament forming metal oxide material such as, e.g., HfOx, ZrOx, etc. An oxygen reservoir layer (e.g., MO) is formed on the ReRAM layer. The oxygen reservoir layer can include materials, such as, e.g., amorphous Ta₂O₅₋ₓ or amorphous WOx. A thin inert layer having a thickness of, e.g., 0.5 nm-5 nm, is disposed on the oxygen reservoir layer. The thin inert layer (e.g., thin conductive cap layer) is formed on the oxygen reservoir layer and has a high work function (e.g., >4.5 eV). The thin inert layer can include materials, such as, e.g., Ru, RuO, Ir, IrO, Pt, etc.

The ReRAM stack structure can be deposited by a reactive sputtering process where in-situ or with fast queue-times are employed to preserve the MO material of the oxygen reservoir layer. The noble metal of the thin inert layer can be used to tune the work function at the oxygen reservoir layer (MO layer) interface and can be used to engineer the reversibility of the ReRAM during write operations.

The ReRAM stack structure in accordance with embodiments of the present invention enables ReRAM devices with a high number of states and low programming noise. The use of the inert layer prevents oxidation of the oxygen reservoir layer (MO layer) in air and improves device forming uniformity by preventing oxygen loss/gain from the MO layer. This is especially useful for analog artificial intelligence (AI) systems (neural networks), where scalability is limited by the non-ideality of non-volatile memory (NVM) devices (e.g., limited number of states, high programming/read noise).

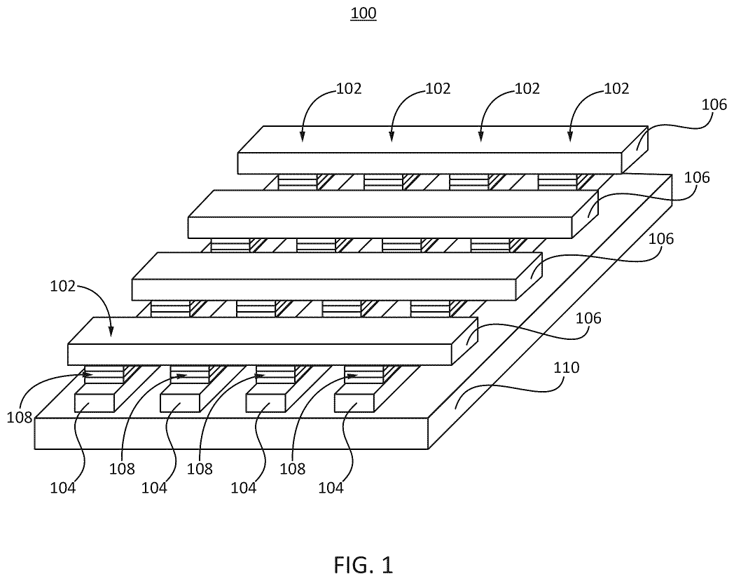

Referring now to the drawings in which like numerals represent the same or similar elements and initially to FIG. 1, a crossbar array 100 is shown having memristors 102 in accordance with embodiments of the present invention. The crossbar array 100 includes a plurality of row electrodes 104 and a plurality of column electrodes 106 arranged in an intersecting pattern on a substrate 110. Memristors 102 are placed at each intersection (crosspoints) of a row electrode 104 and a column electrode 106. The memristors 102 incorporate a ReRAM stack 108 in accordance with embodiments of the present invention.

The ReRAM stack 108 at each crosspoint may include a bottom electrode formed on or as part of the row electrode 104, and a top electrode formed on or as part of the column electrode 106. The ReRAM stack 108 includes an active ReRAM layer, an oxygen reservoir layer and a thin inert cap layer disposed between the top electrodes (106) and the bottom electrodes (104). This arrangement permits each memristor 102 in the array 100 to be individually addressed by selecting the appropriate row and column electrodes.

The crossbar array 100 can be fabricated with the row electrodes 104 formed in a first metal layer, which can be patterned to form metal lines. The ReRAM stack 108 is formed layer-by-layer on top of the first metal layer. The layers of the ReRAM stack 108 can be blanket deposited and patterned to form the ReRAM stack 108 at each crosspoint. A dielectric layer or layers (not shown) can be deposited over the ReRAM stack 108. The column electrodes 106 are formed in a second metal layer above the ReRAM stack 108. Alternatively, the array may be fabricated in a front-end-of-line (FEOL) process integrated with transistor structures.

The crossbar array 100 with the memristors 102 provides a high number of resistance states and low programming noise to allow for more precise tuning of synaptic weights in a neural network. Additionally, the improved forming uniformity and stability provided by the inert cap layer may result in more consistent performance across the array 100.

The crossbar array 100 using the memristors 102 in accordance with the present embodiments can be scalable to very high densities, potentially allowing large neural networks to be implemented in a compact hardware form factor. The non-volatile nature of the memristors 102 also enables persistent storage of synaptic weights without constant power consumption. The crossbar array 100 depicts only four row lines and four column lines. In practice, however, hundreds (or thousands) of lines can be employed. It should be understood that any designation or rows and columns is arbitrary for ease of explanation. The bottom electrodes can be considered rows or columns and the top electrode would correspondingly be considered columns or rows.

In some embodiments, peripheral circuitry may be integrated with the crossbar array 100 to control read and write operations to the individual memristors 102. This may include row and column decoders, sense amplifiers, and programming circuits designed to apply appropriate voltage pulses for setting memristor resistance states. In an embodiment, peripheral circuitry can include analog circuits. For example, a controller is used to program the individual memristors 102 to store values or properties (e.g., electrical conductance) interpretable as values. The memristors 102 may be programmed to store synaptic weights. The crossbar array 100 can correspond to a layer of nodes of an artificial neural network (ANN). The architecture can be larger and/or stacked or interconnected with other crossbar arrays to provide multiple connected layers (e.g., a multilayer network). The crossbar array 100 can be connected to a processor, e.g., including a digital processing unit to successively execute layer operations. Note that while some or all of the circuits for the crossbar array 100 can be analog, each or any of the circuits can be embodied as a digital circuit or processing unit. Suitable converters can be provided to translate signals.

Synaptic weights stored by the memristors 102 can remain constant during inference processing but are reprogrammed during learning processing, e.g., being updated using a back-propagation algorithm. Synaptic weights can be updated using a processor. The crossbar array 100 can be employed for large vector-matrix multiplications or other processing operations.

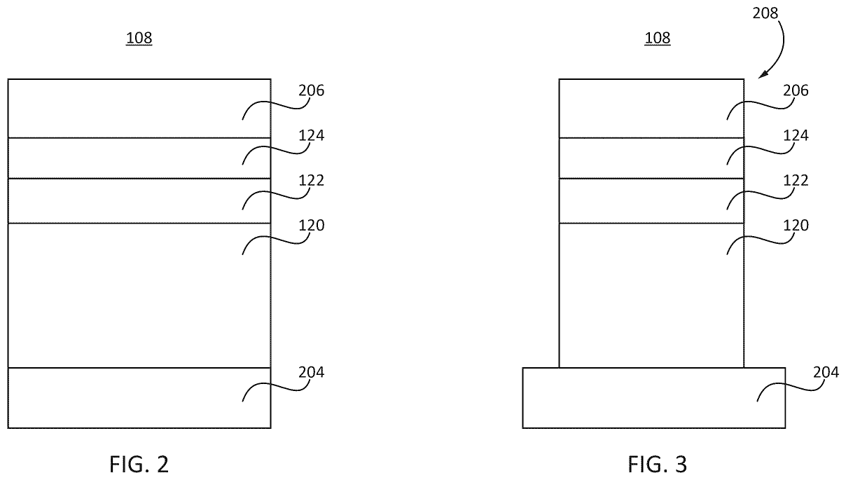

Referring to FIG. 2, a cross-sectional view shows blanket deposited layers of the ReRAM stack 108 in accordance with an embodiment. The ReRAM stack 108 can include multiple layers arranged to achieve desired electrical characteristics and performance. The ReRAM stack 108 includes a bottom electrode 204. The bottom electrode 204 can correspond to the row electrodes 104 described with reference to FIG. 1. The bottom electrode 204 can be formed directly on the substrate (110, FIG. 1) or on an intermediate layer. The bottom electrode 204 can include conductive materials such as, e.g., titanium nitride (TiN), tantalum nitride (TaN), tungsten (W), platinum (Pt).

An active ReRAM layer 120 is deposited on top of the bottom electrode 204. The active ReRAM layer 120 provides a resistive switching mechanism of the memristor 102. The active ReRAM layer 120 can include a filament forming material. A filament forming material includes a material capable of forming conductive filaments within its structure when subjected to an electric field. Filament forming materials can include metal oxides or other insulating materials that can undergo localized changes in their atomic structure to create conductive pathways. These materials may exhibit a change in resistance when voltage is applied, allowing for the storage and manipulation of data in memory devices. The filament forming material forms a filamentary switching layer, which can concentrate current, induce current heating of filaments which increases the mobility of oxygen and its vacancies in the active ReRAM layer 120.

Filament forming materials can include, but are not limited to, hafnium oxide (HfOx), zirconium oxide (ZrOx), crystalline titanium oxide (TiOx), crystalline tantalum oxide (TaOx), etc. In particularly useful embodiments, crystalline TiO₂ and/or crystalline Ta₂O₅ can be employed as filament forming materials (for filamentary switching).

In an embodiment, the active ReRAM layer 120 can include a bilayer with two bulk-switching layers of different materials, but a filamentary switching layer is preferred. Bulk-switching materials can include, e.g., amorphous TiOx or amorphous Ta₂O₅. In other useful embodiments, bulk-switching materials can include praseodymium calcium manganese oxide (PCMO), or other suitable materials. PCMO can include Pr_{0.7}Ca_{0.3}MnO₃ although other stochiometric variations are also contemplated.

An oxygen reservoir layer 122 can be formed on top of the active ReRAM layer 120. The oxygen reservoir layer 122 can include bulk-switching material. The oxygen reservoir layer 122 can include, e.g., a metal oxide (MO) material, such as, e.g., amorphous tungsten oxide, amorphous titanium oxide, amorphous tantalum oxide, praseodymium calcium manganese oxide (PCMO) or other suitable materials. The oxygen reservoir layer 122 serves as a source or sink for oxygen ions during the resistive switching process, enhancing the device's stability and performance. The oxygen reservoir layer 122 needs to have its structure preserved for best performance. Preservation of the oxygen reservoir layer 122 is an important aspect to prevent reaction with air and gettering during deposition of top electrode metals.

A thin inert cap layer 124 is formed on the oxygen reservoir layer 122. The inert cap layer 124 is formed rapidly after the oxygen reservoir layer 122 is fabricated to prevent the oxygen reservoir layer 122 from being altered by oxygen or other effects of later processing. The inert cap layer 124 has minimal gettering of the other ReRAM layers which removes the extra variable of oxygen loss to electrodes during cycling, especially for the oxygen reservoir layer 122, e.g., the bulk switching ReRAM layer.

The inert cap layer 124 can include a thickness ranging from about 0.5 nm to 5 nm and can be deposited on the oxygen reservoir layer 122 in-situ by employing a reactive sputtering process. While other deposition processes can be employed, the deposition process needs to include a fast queue time to ensure minimal exposure to air/oxygen for the oxygen reservoir layer 122. The inert cap layer 124 can include a high work function material (e.g., >4.5 eV) and can include, e.g., ruthenium (Ru), ruthenium oxide (RuO), iridium (Ir), iridium oxide (IrO). The inert cap layer 124 protects the underlying layers from oxidation and may contribute to tuning the work function at the interface with the oxygen reservoir layer 122.

A top electrode 206 can correspond to the column electrodes 106 described with reference to FIG. 1. The top electrode 206 can be formed on the inert cap layer 124. The top electrode 206 can include conductive materials such as, e.g., titanium nitride (TiN), tantalum nitride (TaN), tungsten (W), platinum (Pt) or other conductive materials compatible with the device structure and fabrication process.

The specific arrangement and composition of the layers of the ReRAM stack 108 can provide enhanced stability as the oxygen reservoir layer 122, in combination with the inert cap layer 124, can maintain the oxygen content within the ReRAM stack 108 to improve device stability and uniformity. The use of different materials for each layer of the ReRAM stack 108 may allow for fine-tuning of device characteristics such as switching voltage, resistance states, and endurance. The inert cap layer 124 protects the underlying layers from oxidation and other environmental factors that could degrade device performance.

The ReRAM stack 108 can contribute to reduced noise during programming operations, which may be beneficial for applications requiring high precision. The use of the inert cap layer 124 also enables flexibility in integration permitting the use of standard integrated circuit fabrication materials and processes for the top electrode 206 and later processing.

The oxygen reservoir layer 122, composed of materials like, e.g., amorphous Ta₂O₅−x or amorphous WOₓ, which can exhibit significant instability when exposed to air or subsequent processing steps. For example, when exposed to ambient conditions, the oxygen reservoir layer 122 can rapidly oxidize, altering its stoichiometry and electrical properties. This is particularly evident in WOx, where exposure to air can lead to the formation of WO₃, changing the layer's ability to act as an oxygen reservoir. The oxygen reservoir layer 122 is highly susceptible to changes during subsequent film depositions or processing steps. This sensitivity can result in uncontrolled oxygen loss or gain, affecting the layer's functionality. In experiments, X-ray Photoelectron Spectroscopy (XPS) data reveals significant differences in the chemical composition of WOₓ with and without an in-situ 2 nm TiN inert cap layer (similar to the inert cap layer 124). Uncapped WOₓ shows a predominance of higher oxidation states, while the capped version maintains lower oxidation states and even elemental W (and no WO₃ detected), indicating the cap's effectiveness in preserving the intended composition.

The layers of the ReRAM stack 108 are deposited using a blanket deposition. The blanket deposition can include sequentially depositing each layer of the ReRAM stack 108 over an entire wafer surface. This may include depositing the bottom electrode material, the active ReRAM layer, the oxygen reservoir layer, the inert cap layer, and the top electrode material as continuous films. Physical vapor deposition techniques such as sputtering or evaporation may be used for the metal layers, while atomic layer deposition (ALD) or chemical vapor deposition (CVD) may be employed for the oxide layers to achieve precise thickness control.

Referring to FIG. 3, after blanket deposition of the full stack, a photolithography and etching process may be used to pattern and define the individual memristor devices. This can include applying and patterning a photoresist layer (not shown), then using a subtractive etch process, e.g., reactive ion etching (RIE) or other anisotropic etching techniques, to selectively remove the stack materials in unwanted areas, leaving behind the ReRAM stack 108 that is patterned and the crossbar array. In some embodiments, the sidewalls 208 can be exposed to reactants to form a protection layer to protect the sidewalls 208 from oxygen or other materials.

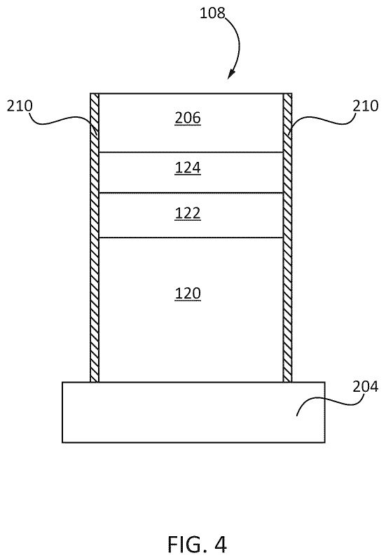

Referring to FIG. 4, in some embodiments, a protection layer 210 may be applied after the etching step to protect the exposed sidewalls of the ReRAM stack 108. This protection layer 210 can help prevent oxidation or contamination of the sensitive layers, particularly the oxygen reservoir layer. The protection layer 210 may be performed by conformally depositing a thin dielectric film such as, e.g., silicon nitride using, e.g., ALD or CVD. The low temperature of the ALD process may help minimize thermal impact to the ReRAM materials.

Alternatively, the etching process itself may incorporate in-situ sidewall passivation by introducing passivating gas species during the reactive ion etching. This may allow a protective liner or other material to form on the sidewalls as etching progresses.

To prevent oxidation of the sides of the ReRAM stack 108, several processing techniques can be employed. In an embodiment, a dep-etch-dep method can be used. This includes depositing the protection layer 210 immediately after etching the ReRAM stack 108. The process flow can include depositing the full ReRAM stack, etching the stack to define the device structure, immediately depositing a conformal passivation layer (e.g., Si₃N₄) to protect the exposed sides. In another embodiment, in-situ sidewall passivation can be employed. During the etching process to from the ReRAM stack 108, a passivation layer can be formed on the sidewalls of the ReRAM stack 108 by reactive ion etching (RIE) with a selected chemistry and introducing passivating gases (e.g., CHF₃ or C₄F₈) during etching to form a protective polymer on the sidewalls of the ReRAM stack 108. In another embodiment, an atomic layer deposition (ALD) encapsulation can be employed. After stack etching, a thin conformal layer can be deposited using ALD to protect the sides of the ReRAM stack 108. Materials like Si₃N₄ can provide an effective oxygen barrier. The low-temperature ALD process minimizes thermal impact on the ReRAM stack 108.

The protection layer 210 can include spacers to protect the sides of the ReRAM stack 108 by depositing a conformal layer of dielectric material (e.g., a nitride) and performing an anisotropic etch to remove the horizontal portions, leaving vertical spacers. These techniques, either individually or in combination, can effectively prevent oxidation of the sides of the ReRAM stack 108, preserving the oxygen reservoir layer 122 and maintaining device performance.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A memristor device, comprising:
a bottom electrode;
an active resistive random-access memory (ReRAM) layer disposed on the bottom electrode;
an oxygen reservoir layer disposed on the active ReRAM layer;
an inert cap layer disposed on the oxygen reservoir layer; and
a top electrode disposed on the inert cap layer.

2. The memristor device of claim 1, wherein the oxygen reservoir layer includes a metal oxide material.

3. The memristor device of claim 2, wherein the metal oxide material is selected from the group consisting of amorphous tungsten oxide, amorphous titanium oxide, amorphous tantalum oxide and praseodymium calcium manganese oxide.

4. The memristor device of claim 1, wherein the inert cap layer comprises a material having a work function above 4.5 eV.

5. The memristor device of claim 4, wherein the material includes ruthenium, iridium or oxides thereof.

6. The memristor device of claim 1, wherein the active ReRAM layer includes a filament forming material.

7. The memristor device of claim 6, wherein the filament forming material is selected from the group consisting of hafnium oxide, zirconium oxide, crystalline titanium oxide and crystalline tantalum oxide.

8. The memristor device of claim 1, further comprising a passivation layer disposed on sidewalls of the oxygen reservoir layer and the inert cap layer.

9. The memristor device of claim 1, wherein the memristor device is included in a crossbar array.

10. A memristor device, comprising:
a bottom electrode;
an active resistive random-access memory (ReRAM) layer disposed on the bottom electrode;
an oxygen reservoir layer disposed on the active ReRAM layer and including a metal oxide;
an inert cap layer disposed on the oxygen reservoir layer, wherein the inert cap layer includes a material having a work function above 4.5 eV; and
a top electrode disposed on the inert cap layer.

11. The memristor device of claim 10, wherein the metal oxide is selected from the group consisting of amorphous tungsten oxide, amorphous titanium oxide, amorphous tantalum oxide and praseodymium calcium manganese oxide.

12. The memristor device of claim 10, wherein the inert cap layer includes ruthenium, iridium or oxides thereof.

13. The memristor device of claim 10, wherein the active ReRAM layer includes a filament forming material.

14. The memristor device of claim 13, wherein the filament forming material is selected from the group consisting of hafnium oxide, zirconium oxide, crystalline titanium oxide and crystalline tantalum oxide.

15. The memristor device of claim 10, further comprising a passivation layer disposed on sidewalls of the oxygen reservoir layer and the inert cap layer.

16. The memristor device of claim 10, wherein the inert cap layer has a thickness between about 0.5 nm and about 5 nm.

17. The memristor device of claim 10, wherein the memristor device is part of a crossbar array.

18. A method of fabricating a memristor device, comprising:
forming a bottom electrode;
depositing an active resistive random-access memory (ReRAM) layer on the bottom electrode;
depositing an oxygen reservoir layer on the active ReRAM layer;
depositing an inert cap layer on the oxygen reservoir layer; and
forming a top electrode on the inert cap layer.

19. The method of claim 18, wherein depositing the oxygen reservoir layer and depositing the inert cap layer are performed in-situ.

20. The method of claim 18, wherein the inert cap layer includes a material having a work function above 4.5 eV.
